(19) United States
(12) Patent Application Publication
(10) Pub. No.: US 2026/0314122 A1
(43) Pub. Date: Oct. 8, 2026

(54) SEMICONDUCTOR DEVICE

(71) Applicant: ENNOSTAR CORPORATION, Hsinchu City (TW)

(72) Inventors: Yi-Chieh LIN, Hsinchu City (TW); Yi-Shan TSAI, Hsinchu City (TW); Yun-Hung WANG, Hsinchu City (TW); Wei Shan YEOH, Hsinchu City (TW); Shih-Chang LEE, Hsinchu City (TW)

(21) Appl. No.: 19/637,769

(22) Filed: Apr. 2, 2026

(30) Foreign Application Priority Data
Apr. 2, 2025 (TW) 114112708

(51) Int. Cl. H10H 20/824; H10H 20/82; H10H 20/831; H10H 20/841

(52) U.S. Cl. CPC H10H 20/8242; H10H 20/82; H10H 20/831; H10H 20/841

(57) ABSTRACT

A semiconductor device includes a semiconductor epitaxial structure and a first electrode. The semiconductor epitaxial structure includes a first semiconductor structure, an active structure and a second semiconductor structure. The first semiconductor structure includes a first semiconductor layer and a second semiconductor layer below the first semiconductor layer, and the first semiconductor layer has an upper surface including a first region and a second region. The active structure and the second semiconductor structure are located on the first region and do not overlap with the second region. The first electrode is located on the second region and directly contacts the first semiconductor layer. The first semiconductor layer is n-type and is the thickest layer within the first semiconductor structure, and the first semiconductor layer includes a ternary or quaternary arsenide, or a ternary or quaternary phosphide.

### TECHNICAL FIELD

The present disclosure relates to a semiconductor device, and particularly to a semiconductor device capable of emitting light.

### Cross Reference to Related Application

This application claims the right of priority based on TW Application Serial No. 114112708, filed on Apr. 02, 2025, which is hereby incorporated by reference in its entirety.

### Description of Background Art

Group III-V semiconductor materials including Group III and Group V elements may be used to produce various semiconductor devices, such as semiconductor optoelectronic devices like light-emitting diodes (LEDs), laser diodes (LDs), photodetectors or solar cells, or may be used in power devices, such as switching devices or rectifiers. These semiconductor optoelectronic devices may be applied to products in various fields, such as illumination, medical, display, communication, sensing or power supply system. Light-emitting diodes and laser diodes are light-emitting devices, and their basic structures may include a p-type semiconductor, an n-type semiconductor and an active structure located between the p-type semiconductor and the n-type semiconductor. By introducing current, carriers may recombine in the active structure and emit light, and wavelength of the light depends on the semiconductor material in the active structure.

### Summary of the Disclosure

The present disclosure provides a semiconductor device. The semiconductor device includes a semiconductor epitaxial structure and a first electrode. The semiconductor epitaxial structure includes a first semiconductor structure, an active structure and a second semiconductor structure. The first semiconductor structure includes a first semiconductor layer and a second semiconductor layer below the first semiconductor layer, and the first semiconductor layer has an upper surface including a first region and a second region. The active structure and the second semiconductor structure are located on the first region and do not overlap with the second region. The first electrode is located on the second region and directly contacts the first semiconductor layer. The first semiconductor layer is n-type and is the thickest layer within the first semiconductor structure, and the first semiconductor layer includes a ternary or quaternary arsenide, or a ternary or quaternary phosphide.

### BRIEF DESCRIPTION OF THE DRAWINGS

FIG. 1 shows a schematic sectional view of a semiconductor epitaxial structure according to one embodiment of the present disclosure;

FIG. 2A shows a schematic top view of a semiconductor device according to one embodiment of the present disclosure;

FIG. 2B shows a schematic sectional view of the semiconductor device along sectional line X-X’ of FIG. 2A;

FIG. 3A shows a schematic top view of a semiconductor device according to one embodiment of the present disclosure;

FIG. 3B shows a schematic sectional view of the semiconductor device along sectional line A-B of FIG. 3A;

FIG. 3C shows a schematic sectional view of the semiconductor device along sectional line C-D of FIG. 3A;

FIG. 3D shows a schematic sectional view of the semiconductor device along sectional line E-F of FIG. 3A;

FIG. 4 shows a schematic top view of a semiconductor device according to one embodiment of the present disclosure;

FIG. 5 shows a schematic top view of a semiconductor device according to one embodiment of the present disclosure;

FIG. 6 shows a schematic top view of a semiconductor device according to one embodiment of the present disclosure;

FIG. 7 shows a schematic sectional view of a semiconductor apparatus according to one embodiment of the present disclosure.

### DETAILED DESCRIPTION OF PREFERRED EMBODIMENTS

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula InGaN represents Inₓ₂Ga₁₋ₓ₂N, wherein 0<x2<1; the general formula AlGaN represents Alₓ₃Ga₁₋ₓ₃N, wherein 0<x3<1; the general formula AlGaInP represents Alₓ₄Gaₓ₅In₁₋ₓ₄₋ₓ₅P, wherein 0<x4<1, and 0<x5<1; the general formula InGaAsP represents Inₓ₆Ga₁₋ₓ₆Asₓ₇P₁₋ₓ₇, wherein 0<x6<1, and 0<x7<1; the general formula AlGaInAs represents Alₓ₈Gaₓ₉In₁₋ₓ₈₋ₓ₉As, wherein 0<x8<1, and 0<x9<1; the general formula InGaNAs represents Inₓ₁₀Ga₁₋ₓ₁₀Nₓ₁₁As₁₋ₓ₁₁, wherein 0<x10<1, and 0<x11<1; the general formula InGaAs represents Inₓ₁₂Ga₁₋ₓ₁₂As, wherein 0<x12<1; the general formula AlGaAs represents Alₓ₁₃Ga₁₋ₓ₁₃As, wherein 0<x13<1; the general formula AlInGaN represents Alₓ₁₄Inₓ₁₅Ga₁₋ₓ₁₄₋ₓ₁₅N, wherein 0<x14<1, and 0<x15<1; and the general formula AlGaAsP represents Alₓ₁₆Ga₁₋ₓ₁₆Asₓ₁₇P₁₋ₓ₁₇, wherein 0<x16<1, and 0<x17<1. The content of each element may be adjusted for different purposes, for example, for adjusting the band gap, or for adjusting a dominant wavelength or a peak wavelength of a light emitting device. However, the present disclosure is not limited thereto.

The semiconductor device of the present disclosure is, for example, a semiconductor optoelectronic device or a non-optoelectronic device. The semiconductor optoelectronic device includes a light-emitting device (such as a light-emitting diode or a laser diode), or a light absorbing device (such as a photo-detector). The qualitative or quantitative analysis of the composition and/or dopant contained in each layer of the semiconductor device of the present disclosure may be conducted by any suitable method, for example, by secondary ion mass spectrometer (SIMS). A thickness of each layer may be obtained by any suitable method, for example, by transmission electron microscopy (TEM) or scanning electron microscope (SEM). If not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

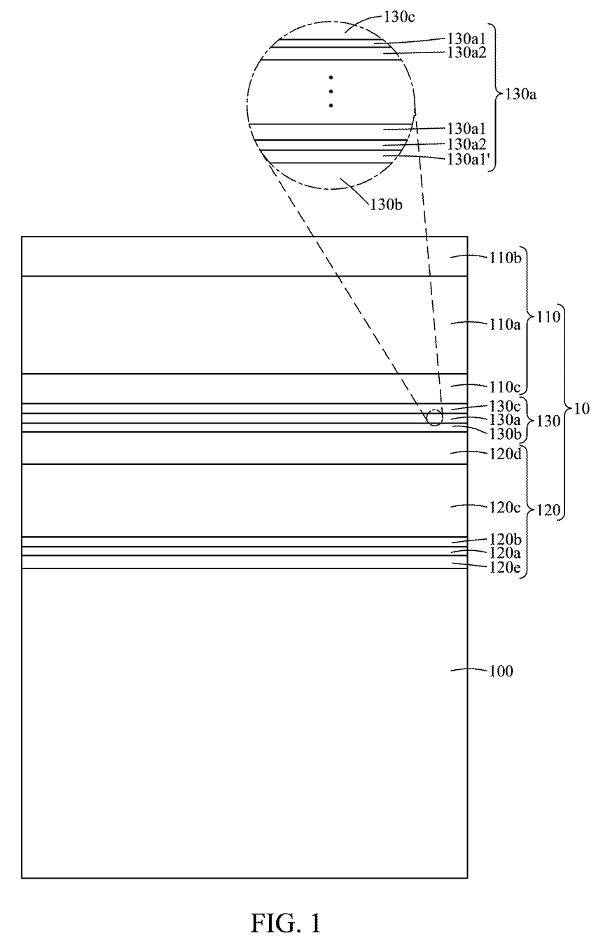

FIG. 1 is a schematic sectional view of a semiconductor epitaxial structure 10 in accordance with one embodiment of the present disclosure. As shown in FIG. 1, the semiconductor epitaxial structure 10 includes a first semiconductor structure 110, a second semiconductor structure 120, and an active structure 130 disposed between the first semiconductor structure 110 and the second semiconductor structure 120. The first semiconductor structure 110 and the second semiconductor structure 120 may have different conductivity types. For example, the first semiconductor structure 110 may be n-type and the second semiconductor structure 120 may be p-type, or the first semiconductor structure 110 may be p-type and the second semiconductor structure 120 may be n-type. In some embodiments, the first semiconductor structure 110 and the second semiconductor structure 120 may respectively provide electrons and holes (or holes and electrons), which recombine in the active structure 130 to emit a light having a specific wavelength. The light may include visible light or invisible light. The conductivity types of each layer of the first semiconductor structure 110 and each layer of the second semiconductor structure 120 can be adjusted by introducing different dopants. The dopants may be a Group II element, a Group IV element, or a Group VI element, such as magnesium (Mg), zinc (Zn), carbon (C), silicon (Si), or tellurium (Te). The semiconductor epitaxial structure 10 can be formed by epitaxial methods such as metal-organic chemical vapor deposition (MOCVD), molecular beam epitaxy (MBE), or hydride vapor phase epitaxy (HVPE).

The semiconductor epitaxial structure 10 may include a growth substrate 100 for forming the semiconductor epitaxial structure 10. As shown in FIG. 1, the growth substrate 100 is located below the first semiconductor structure 110, the second semiconductor structure 120, and the active structure 130, and is adjacent to the second semiconductor structure 120. The growth substrate 100 may be used for epitaxial growth, and may include sapphire, gallium nitride (GaN), silicon (Si), gallium arsenide (GaAs), indium phosphide (InP), or gallium phosphide (GaP). According to some embodiments, the growth substrate 100 and the second semiconductor structure 120 may have different conductivity types. For example, the growth substrate 100 may be n-type while the second semiconductor structure 120 may be p-type, or the growth substrate 100 may be p-type while the second semiconductor structure 120 may be n-type. In some embodiments, a p-type second semiconductor structure 120 and an n-type first semiconductor structure 110 can be sequentially formed on an n-type growth substrate 100.

The semiconductor epitaxial structure 10 may include a double heterostructure (DH), a double-side double heterostructure (DDH) or a multiple quantum well (MQW) structure. The first semiconductor structure 110, the second semiconductor structure 120, and/or the active structure 130 may include a III-V semiconductor material. The III-V semiconductor material may include aluminum (Al), gallium (Ga), arsenic (As), phosphorus (P), or indium (In). Specifically, the III-V semiconductor material can be a binary compound semiconductor (such as GaAs, GaP or GaN), a ternary compound semiconductor (such as InGaAs, AlGaAs, InGaP, AlInP, InGaN or AlGaN) or a quaternary compound semiconductor (such as AlGaInAs, AlGaInP, AlInGaN, InGaAsP, InGaAsN or AlGaAsP). In an embodiment, the active structure 130 only include a ternary compound semiconductor (such as InGaAs, AlGaAs, InGaP, AlInP, InGaN, or AlGaN) or a quaternary compound semiconductor (such as AlGaInAs, AlGaInP, AlInGaN, InGaAsP, InGaAsN, or AlGaAsP). In some embodiments, the III-V semiconductor materials of the first semiconductor structure 110, the second semiconductor structure 120, and the active structure 130 do not include nitrogen (N).

When the semiconductor epitaxial structure 10 is applied in a light-emitting device, the light emitted from the active structure 130 may have a peak wavelength determined by the material composition of the active structure 130. For example, when the material of the active structure 130 includes AlGaN, it may emit ultraviolet light with a peak wavelength of 250 nm to 400 nm; when the material of the active structure 130 includes InGaN, it may emit deep blue light or blue light with a peak wavelength of 400 nm to 490 nm, green light with a peak wavelength of 490 nm to 550 nm, or yellow light or red light with a peak wavelength of 560 nm to 650 nm; when the material of the active structure 130 includes InGaP or AlGaInP, it may emit yellow light, orange light or red light with a peak wavelength of 530 nm to 700 nm; when the material of the active structure 130 includes InGaAs, InGaAsP, AlGaAs or AlGaInAs, it may emit infrared light with a peak wavelength of 700 nm to 1700 nm.

The first semiconductor structure 110 and the second semiconductor structure 120 may respectively be a single layer or multiple layers. As shown in FIG. 1, the first semiconductor structure 110 includes a first semiconductor layer 110a, a second semiconductor layer 110b, and a third semiconductor layer 110c. The second semiconductor structure 120 includes a fourth semiconductor layer 120a, a sixth semiconductor layer 120c, and a seventh semiconductor layer 120d, and optionally includes a fifth semiconductor layer 120b and an eighth semiconductor layer 120e. As shown in FIG. 1, the third semiconductor layer 110c and the seventh semiconductor layer 120d are adjacent to and connect to the active structure 130.

The first semiconductor layer 110a and/or the sixth semiconductor layer 120c may be a window layer to improve the light extraction efficiency and/or the uniformity of current spreading of the semiconductor epitaxial structure 10. The first semiconductor layer 110a and the sixth semiconductor layer 120c may be transparent to the light emitted from the active structure 130. In some embodiments, the first semiconductor layer 110a and the sixth semiconductor layer 120c may include the same or different III-V semiconductor materials. In some embodiments, the first semiconductor layer 110a includes a first III-V semiconductor material. The first III-V semiconductor material may include a ternary or quaternary arsenide or a ternary or quaternary phosphide which includes aluminum, such as AlGaAs, AlInP or AlGaInP. In some embodiments, the sixth semiconductor layer 120c includes a sixth III-V semiconductor material. The sixth III-V semiconductor material may include a ternary or quaternary arsenide or a ternary or quaternary phosphide which includes aluminum, such as AlGaAs or AlGaInP.

The first semiconductor layer 110a may also be a contact layer for forming a good electric contact (e.g., an ohmic contact) with a metal. In some embodiments, the first semiconductor layer 110a can be the thickest layer of the first semiconductor structure 110, and concurrently provide current-spreading and electric contact functions. In some embodiments, the first III-V semiconductor material can be an n-type compound semiconductor (e.g., n-AlGaAs or n-AlGaInP), which has a lower band gap and better carrier mobility than a p-type compound semiconductor (e.g., p-GaP). In some embodiments, the first III-V semiconductor material has a band gap larger than that of the growth substrate 100 (e.g., GaAs) and less than that of GaP, and/or a difference between a lattice constant of the first III-V semiconductor material and a lattice constant of the material of the growth substrate 100 may be smaller than a difference between a lattice constant of GaP and the lattice constant of the material of the growth substrate 100. Thus, the epitaxial quality of the first semiconductor layer 110a can be improved, and the first semiconductor layer 110a can readily form a good electric contact with metal.

In some embodiments, the first semiconductor layer 110a may have a thickness in a range from 2 μm to 8 μm, so as to improve current spreading within the first semiconductor layer 110a. The first semiconductor layer 110a may include a first dopant, and the first dopant may have a concentration in a range from 5×10¹⁷ cm⁻³ to 5×10¹⁸ cm⁻³. For example, when the first III-V semiconductor material includes Al_{y1}Ga_{(1-y1)}As and 0<y1<0.2, the concentration of the first dopant in the first semiconductor layer 110a can be equal to or higher than 5×10¹⁷ cm⁻³ or higher; when the first III-V semiconductor material includes Al_{y2}In_{(1-y2)}P and 0.45<y2<0.55, the concentration of the first dopant in the first semiconductor layer 110a can be equal to or higher than 1×10¹⁸ cm⁻³; or when the first III-V semiconductor material includes (Al_{y3}Ga_{(1-y3)})_{(1-y4)}In_{y4}P and 0<y3<0.6 and 0.45<y4<0.55, the concentration of the first dopant in the first semiconductor layer 110a can be equal to or higher than 1×10¹⁸ cm⁻³. In above embodiments, y1, y2, and y3 respectively represent aluminum content of the first semiconductor layer 110a. Through setting the thickness of the first semiconductor layer 110a and/or the concentration of the first dopant within the above ranges, a wall-plug efficiency (WPE) of a semiconductor device fabricated by the semiconductor epitaxial structure 10 can be improved, so that a forward voltage of a semiconductor device made by the semiconductor epitaxial structure 10 can be reduced, and a brightness of the semiconductor device can be increased.

The second semiconductor layer 110b may be a bonding support layer. In some embodiments, the second semiconductor layer 110b includes a second III-V semiconductor material, which is different from the first III-V semiconductor material. In some embodiments, the second III-V semiconductor material may include a binary III-V compound semiconductor, a ternary compound semiconductor, or a quaternary III-V compound semiconductor, such as GaP, GaAs, AlGaAs, or AlGaInP. The second semiconductor layer 110b may have a thickness smaller than that of the first semiconductor layer 110a. For example, the second semiconductor layer 110b may have a thickness in a range from 1 μm to 3 μm. In some embodiments, when the first semiconductor structure 110 is to be bonded to a base (not shown), disposing the second semiconductor layer 110b in the first semiconductor structure 110 can improve the stability of the bonding process. The second semiconductor layer 110b may include dopants or may be undoped. In some embodiments, the second semiconductor layer 110b includes a second dopant, and the second dopant may be the same as or different from the first dopant. In some embodiments, the second dopant in the second semiconductor layer 110b may have a concentration not larger than 1×10¹⁶ cm⁻³, such as 1×10¹⁵ cm⁻³.

In some embodiments, the third semiconductor layer 110c and the seventh semiconductor layer 120d are adjacent to and connect to the active structure 130 and may be cladding layers to provide electrons and holes (or holes and electrons) respectively. Specifically, the third semiconductor layer 110c is disposed between the first semiconductor layer 110a and the active structure 130, and the seventh semiconductor layer 120d is disposed between the sixth semiconductor layer 120c and the active structure 130. In some embodiments, the third semiconductor layer 110c includes a third III-V semiconductor material, and the seventh semiconductor layer 120d includes a seventh III-V semiconductor material, and the third III-V semiconductor material and the seventh III-V semiconductor material can be the same or different. The third III-V semiconductor material and the seventh III-V semiconductor material may respectively be a ternary or quaternary arsenide or a ternary or quaternary phosphide which includes aluminum, such as AlGaAs. The third III-V semiconductor material of the third semiconductor layer 110c and the first III-V semiconductor material of the first semiconductor layer 110a may include the same material. In some embodiments, the first semiconductor layer 110a has a thickness larger than that of the third semiconductor layer 110c to ensure enough current spreading effect, and the first III-V semiconductor material has an aluminum content smaller than that of the third III-V semiconductor material to lower the forward voltage of the semiconductor device made by the semiconductor epitaxial structure 10. The seventh III-V semiconductor material of the seventh semiconductor layer 120d and the sixth III-V semiconductor material of the sixth semiconductor layer 120c may include the same material. In some embodiments, the sixth semiconductor layer 120c has a thickness larger than that of the seventh semiconductor layer 120d to ensure enough current spreading effect, and the sixth III-V semiconductor material has an aluminum content smaller than that of the seventh III-V semiconductor material to lower the forward voltage of the semiconductor device made by the semiconductor epitaxial structure 10.

The third semiconductor layer 110c may include a third dopant, and the third dopant can be the same as or different from the first dopant or the second dopant. In some embodiments, the third dopant in the third semiconductor layer 110c may have a concentration in a range from 1×10¹⁷ cm⁻³ to 1×10¹⁸ cm⁻³. The first dopant, the second dopant and the third dopant may be selected from Group II, Group IV, or Group VI elements of the periodic table, such as magnesium (Mg), zinc (Zn), carbon (C), silicon (Si), sulfur (S), selenium (Se), germanium (Ge), or tellurium (Te). In some embodiments, the first dopant, the second dopant, and the third dopant may respectively be silicon (Si), sulfur (S), selenium (Se), germanium (Ge), or tellurium (Te).

The fourth semiconductor layer 120a may be a contact layer for forming good electric contact with metal. The fourth semiconductor layer 120a includes a fourth III-V semiconductor material. The fourth III-V semiconductor material may include a binary III-V compound semiconductor or a ternary III-V compound semiconductor, such as GaAs, GaP, or AlGaAs. In some embodiments, the fourth III-V semiconductor material includes Al_{y5}Ga_{(1-y5)}As, wherein 0<y5<0.2. The fourth semiconductor layer 120a may include a fourth dopant. The fourth semiconductor layer 120a may have a doping concentration larger than that of the sixth semiconductor layer 120c. In some embodiments, the fourth dopant in the fourth semiconductor layer 120a may have a concentration in a range from 5×10¹⁸ cm⁻³ to 5×10¹⁹ cm⁻³.

Referring to FIG. 1, the fifth semiconductor layer 120b is disposed between the fourth semiconductor layer 120a and the sixth semiconductor layer 120c, and the eighth semiconductor layer 120e is disposed between the fourth semiconductor layer 120a and the growth substrate 100, and the fourth semiconductor layer 120a is located between the fifth semiconductor layer 120b and the eighth semiconductor layer 120e. In some embodiments, the fifth semiconductor layer 120b and/or the eighth semiconductor layer 120e may be a transition layer. For example, when there is a lattice mismatch between the materials of the fourth semiconductor layer 120a and the sixth semiconductor layer 120c, the fifth semiconductor layer 120b may reduce the stress induced by the lattice mismatch; or when there is a lattice mismatch between the materials of the fourth semiconductor layer 120a and the growth substrate 100, the eighth semiconductor layer 120e may reduce stress induced by the lattice mismatch. In some embodiments, the fifth semiconductor layer 120b and/or the eighth semiconductor layer 120e may also be an etch stop layer.

The fifth semiconductor layer 120b includes a fifth III-V semiconductor material, and the eighth semiconductor layer 120e includes an eighth III-V semiconductor material. In some embodiments, the fifth III-V semiconductor material and the eighth III-V semiconductor material may respectively include a ternary III-V compound semiconductor, such as InGaP. In some embodiments, the fifth semiconductor layer 120b and/or the eighth semiconductor layer 120e may have a thickness larger than that of the fourth semiconductor layer 120a.

In some embodiments, the fifth semiconductor layer 120b, the sixth semiconductor layer 120c, the seventh semiconductor layer 120d, and the eighth semiconductor layer 120e may respectively include a fifth dopant, a sixth dopant, a seventh dopant, and an eighth dopant. Any two among the fourth dopant, the fifth dopant, the sixth dopant, the seventh dopant, and the eighth dopant may be the same or different. In some embodiments, the fifth dopant in the fifth semiconductor layer 120b may have a concentration in a range from 8×10¹⁷ cm⁻³ to 8×10¹⁸ cm⁻³; the sixth dopant in the sixth semiconductor layer 120c may have a concentration in a range from 1×10¹⁷ cm⁻³ to 2×10¹⁹ cm⁻³; the seventh dopant in the seventh semiconductor layer 120d may have a concentration in a range from 5×10¹⁷ cm⁻³ to 5×10¹⁸ cm⁻³; the eighth dopant in the eighth semiconductor layer 120e may have a concentration in a range from 8×10¹⁷ cm⁻³ to 8×10¹⁸ cm⁻³. The fourth dopant, the fifth dopant, the sixth dopant, the seventh dopant, and the eighth dopant may be selected from Group II, Group IV, or Group VI elements of the periodic table, such as magnesium (Mg), zinc (Zn), carbon (C), silicon (Si), beryllium (Be), sulfur (S), selenium (Se), germanium (Ge), or tellurium (Te). In some embodiments, the fourth dopant, the fifth dopant, the sixth dopant, the seventh dopant, and the eighth dopant may respectively be magnesium (Mg), zinc (Zn), beryllium (Be), or carbon (C).

The semiconductor epitaxial structure 10 may optionally include a buffer layer (not shown) disposed between the growth substrate 100 and the second semiconductor structure 120. The buffer layer may compensate a lattice constant difference between the growth substrate 100 and the second semiconductor structure 120 or may suppress epitaxial defects, thereby preventing epitaxial defects from propagating from the growth substrate 100 into the second semiconductor structure 120 to improve epitaxial quality. In some embodiments, the buffer layer may reduce the influence of dopants in the growth substrate 100 on epitaxial growth of the semiconductor epitaxial structure 10. In some embodiments, the buffer layer includes a binary III–V compound semiconductor, such as GaAs.

Referring to FIG. 1, the active structure 130 is shown as the multi-quantum well (MQW) structure. In this embodiment, the active structure 130 includes a semiconductor stack 130a. The semiconductor stack 130a includes N pairs of alternately stacked barrier layers 130a1 and well layers 130a2. In some embodiments, N is a positive integer larger than or equal to 1 and smaller than or equal to 15. The semiconductor stack 130a may optionally include an additional barrier layer 130a1’ connected to the well layer 130a2 of the Nth pair of the barrier layer 130a1 and the well layer 130a2. The active structure 130 may further include a first confinement layer 130b and a second confinement layer 130c, and the semiconductor stack 130a is disposed between the first confinement layer 130b and the second confinement layer 130c. The first confinement layer 130b and the second confinement layer 130c may respectively be a single layer or multiple sublayers.

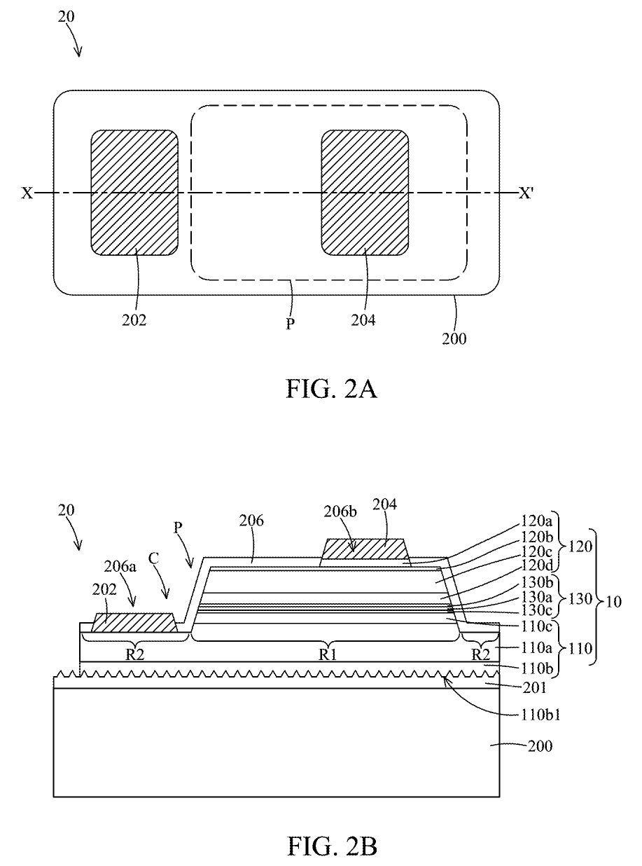

The semiconductor epitaxial structure 10 may be applied to fabricate semiconductor devices or semiconductor apparatuses. The structures of semiconductor devices and semiconductor apparatuses are exemplified with reference to FIGS. 2A through 7. FIG. 2A is a schematic top view of a semiconductor device 20 in accordance with one embodiment of the present disclosure. FIG. 2B is a schematic sectional view of the semiconductor device 20 along sectional line X-X’ in FIG. 2A. As shown in FIGS. 2A and 2B, the semiconductor device 20 includes the semiconductor epitaxial structure 10, a first electrode 202 and a second electrode 204, and the semiconductor epitaxial structure 10 includes a recess portion C. The recess portion C may be formed by removing the second semiconductor structure 120, the active structure 130, and a portion of the first semiconductor structure 110 by wet etching or dry etching, and the first semiconductor layer 110a is exposed at a bottom of the recess portion C. In this embodiment, as shown in FIG. 2B, the second semiconductor structure 120, the active structure 130, and another portion of the first semiconductor structure 110 form a platform portion P. Specifically, as shown in FIG. 2B, the first semiconductor layer 110a includes a first region R1 and a second region R2. The second semiconductor structure 120 and the active structure 130 are disposed on the first region R1 and are not overlapped with the second region R2. In some embodiments, the second region R2 surrounds the first region R1.

As shown in FIG. 2B, the first electrode 202 is disposed on the second region R2. Specifically, the first electrode 202 is disposed on and directly contacts the first semiconductor layer 110a to form electrical connection with the first semiconductor layer 110a. The second electrode 204 is disposed on the second semiconductor structure 120. Specifically, the second electrode 204 is disposed on and directly contacts the fourth semiconductor layer 120a. In top view, the first electrode 202 and the second electrode 204 may respectively be circular, elliptical, rectangular, or other polygonal shapes. In some embodiments, the fourth semiconductor layer 120a may be a patterned semiconductor layer, and the fourth semiconductor layer 120a may have a width same as that of the second electrode 204. The fifth semiconductor layer 120b may have a width larger than that of the fourth semiconductor layer 120a. In some embodiments, the material of the fourth semiconductor layer 120a may absorb the light emitted from the active structure 130, and patterning the fourth semiconductor layer 120a can reduce absorption of the light emitted from the active structure 130, so as to increase light emission intensity of the semiconductor device 20.

The semiconductor device 20 may optionally include an insulation structure 206 that covers the semiconductor epitaxial structure 10. In some embodiments, the insulation structure 206 includes a first opening 206a and a second opening 206b respectively corresponding to the first electrode 202 and the second electrode 204. The insulation structure 206 may provide insulation, and/or protection functions, for example isolating external moisture or contaminants to prevent damage to the semiconductor epitaxial structure 10 and to prevent forming leakage paths in the semiconductor device 20. The insulation structure 206 may be a single layer or multiple layers, and includes a dielectric material such as an oxide, a nitride, a polymer, or combinations thereof. The oxide may include aluminum oxide (AlOx), silicon oxide (SiOx), titanium oxide (TiOx), niobium pentoxide (Nb₂O₅), or tantalum pentoxide (Ta₂O₅). The nitride may include aluminum nitride (AlN) or silicon nitride (SiNx). The polymer may include polyimide or benzocyclobutene (BCB). The insulation structure 206 may further have a reflective function, so the semiconductor device 20 emits light from a side of the first semiconductor structure 110. In some embodiments, the insulation structure 206 may include a Distributed Bragg Reflector (DBR). The DBR includes a plurality of first dielectric layers and a plurality of second dielectric layers (not shown) that are alternately stacked with each other, and the plurality of first dielectric layers and the plurality of second dielectric layers have different refractive indices. The first dielectric layer and the second dielectric layer may respectively include aluminum oxide (Al₂O₃), silicon dioxide (SiO₂), titanium dioxide (TiO₂), or niobium pentoxide (Nb₂O₅). The combinations of the first dielectric layer and the second dielectric layer may include SiO₂/Al₂O₃, SiO₂/TiO₂, or SiO₂/Nb₂O₅.

The first electrode 202 and the second electrode 204 include, for example, a transparent conductive material, a metal, or an alloy. The transparent conductive material includes a metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include titanium (Ti), germanium (Ge), beryllium (Be), zinc (Zn), gold (Au), silver (Ag), platinum (Pt), nickel (Ni), or copper (Cu). The alloy may include two or more of the above metal elements, such as germanium-gold-nickel (GeAuNi), beryllium-gold (BeAu), germanium-gold (GeAu), zinc-gold (ZnAu), or titanium-gold (TiAu). The first electrode 202 and the second electrode 204 may include the same or different materials. In some embodiments, the first electrode 202 includes germanium–gold (GeAu), and the second electrode 204 includes beryllium–gold (BeAu) or titanium–gold (TiAu). In some embodiments, the second electrode 204 includes indium tin oxide (ITO), indium zinc oxide (IZO), gold (Au), or silver (Ag).

The semiconductor device 20 may optionally include a base 200 and a bonding structure 201. The base 200 is disposed below the first semiconductor structure 110, and the bonding structure 201 is disposed between the base 200 and the first semiconductor structure 110 to connect them. The base 200 may be a bonding substrate, and may include an insulating material, such as sapphire or glass. The bonding structure 201 may include a nitride (such as silicon nitride (SiNx)), an oxide (such as tantalum oxide (TaOx), aluminum oxide (AlOx), silicon oxide (SiOx), or titanium oxide (TiOx)), or a polymer (such as benzocyclobutene (BCB), epoxy, polyimide, or silicone). In some embodiments, when the first semiconductor layer 110a is n-type and is the thickest layer of the first semiconductor structure 110, the lateral current conduction of the first semiconductor structure 110 can be improved, thereby the optoelectronic characteristics of the semiconductor device 20 are optimized. For example, compared with a semiconductor device in which the first semiconductor layer 110a includes a p-type semiconductor (e.g., p-GaP), a semiconductor device in which the first semiconductor layer 110a includes an n-type semiconductor (e.g., n-AlGaAs or n-AlGaInP) has better current-spreading performance, lower forward voltage and higher brightness.

In some embodiments, a method of manufacturing the semiconductor device 20 includes the following steps: providing the semiconductor epitaxial structure 10; performing a bonding process to bond the first semiconductor structure 110 to the base 200 by the bonding structure 201; removing the growth substrate 100 from the semiconductor epitaxial structure 10; removing a portion of the first semiconductor structure 110, the second semiconductor structure 120, and the active structure 130 to form the recess portion C and the platform portion P; forming the first electrode 202 in the recess portion C, and forming the second electrode 204 on the fourth semiconductor layer 120a. In some embodiments, the method of manufacturing the semiconductor device 20 optionally includes a step: removing the base 200 and the bonding structure 201 after forming the first electrode 202 and the second electrode 204. As shown in FIG. 2B, a bottom surface 110b1 of the second semiconductor layer 110b may be roughened to form a textured structure to further improve the light extraction efficiency of the semiconductor device 20. In some embodiments, an average roughness (Ra) of the bottom surface 110b1 may be less than 0.15 µm, for example in a range from 0.09 µm to 0.14 µm. The positions, relative relationships and materials of each layer or structure as well as variations of the semiconductor device 20 may be referred to the foregoing embodiments and are not repeatedly described herein.

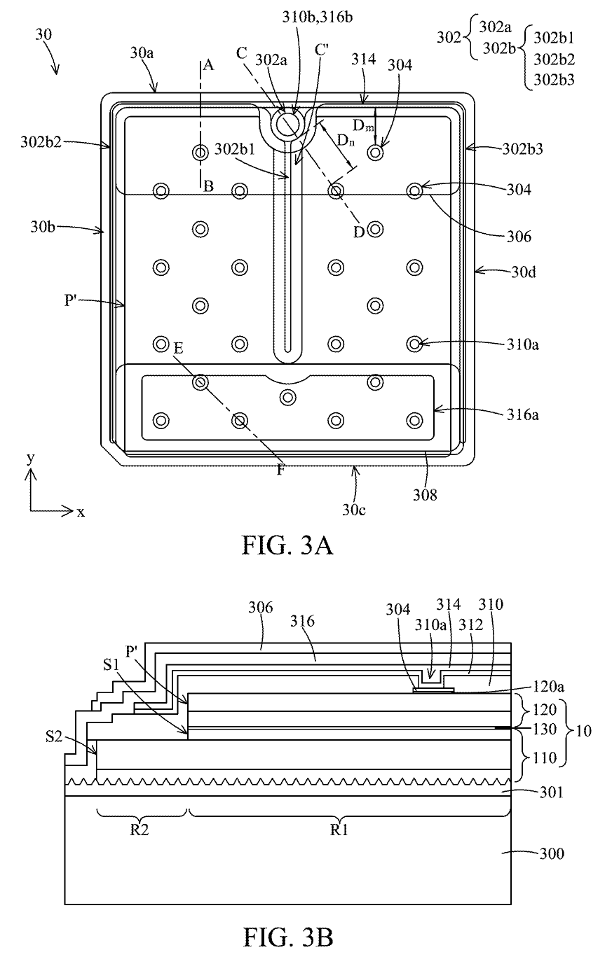

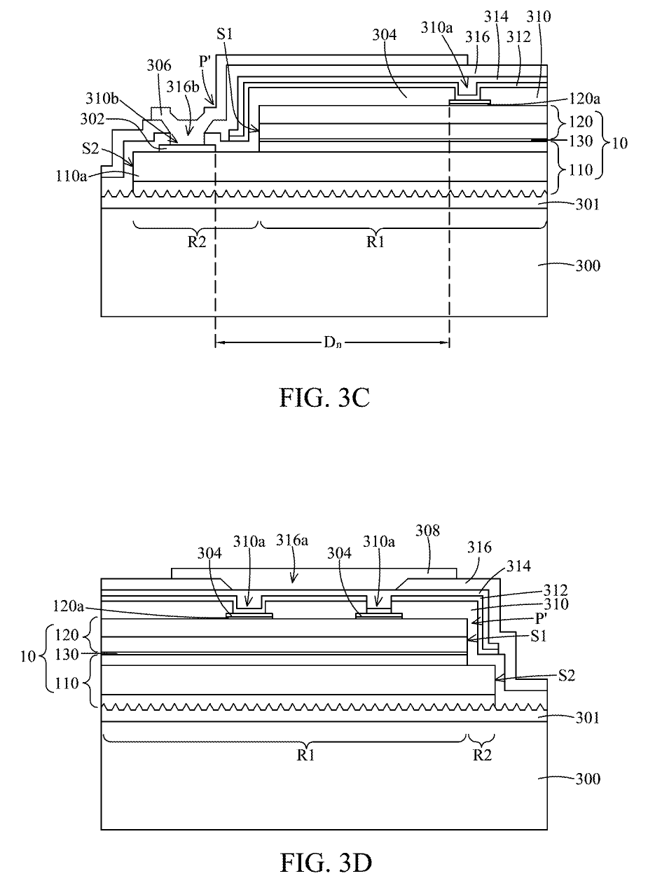

FIG. 3A is a schematic top view of a semiconductor device 30 in accordance with an embodiment of the present disclosure. FIG. 3B is a schematic sectional view of the semiconductor device 30 along sectional line A-B shown in FIG. 3A. FIG. 3C is a schematic sectional view of the semiconductor device 30 along sectional line C-D shown in FIG. 3A. FIG. 3D is a schematic sectional view of the semiconductor device 30 along sectional line E-F shown in FIG. 3A. As shown in FIG. 3A, in top view, the semiconductor device 30 includes a first side 30a, a second side 30b, a third side 30c, and a fourth side 30d. The first side 30a is opposite to the third side 30c, and the second side 30b is opposite to the fourth side 30d. The semiconductor device 30 includes the semiconductor epitaxial structure 10, a first electrode 302 and a plurality of second electrodes 304 that are separated from one another. In this embodiment, the semiconductor epitaxial structure 10 includes a platform portion P’ and a recess portion C’. The first electrode 302 is disposed in the recess portion C’ and is in direct contact with the first semiconductor layer 110a. The plurality of second electrodes 304 are in direct contact with the fourth semiconductor layer 120a.

As shown in FIG. 3A, the first electrode 302 includes a main portion 302a and an extending portion 302b. In this embodiment, the extending portion 302b includes a plurality of finger electrodes 302b1, 302b2, and 302b3. Each of the finger electrodes 302b1, 302b2, and 302b3 may have a sectional width smaller than that of the main portion 302a. Specifically, the finger electrode 302b1 directly connects to the main portion 302a and extends toward the third side 30c; the finger electrode 302b2 directly connects to the main portion 302a, first extends along the first side 30a and then turns to extend along the second side 30b; and the finger electrode 302b3 directly connects to the main portion 302a, first extends along the first side 30a and then turns to extend along the fourth side 30d. In some embodiments, by adopting the extending portion design described above, current spreading within the semiconductor device 30 can be further improved, which helps increase luminous efficiency.

As shown in FIGS. 3A to 3D, the plurality of second electrodes 304 may be arranged in a two-dimensional array. Each of the second electrodes 304 may have a shape such as circular, elliptical, rounded rectangular, or another shape. For each of the second electrodes 304, a maximum value of the sectional width may be in a range from 7 µm to 20 µm. In some embodiments, a shortest distance between the second electrode 304 and the extending portion 302b of the first electrode 302 (e.g., the distance Dm shown in FIG. 3A) may be in a range from 25 µm to 70 µm. In some embodiments, a shortest distance between the main portion 302a of the first electrode 302 and the second electrode 304 (e.g., the distance Dn shown in FIGS. 3A and 3C) may be in a range from 25 µm to 70 µm. By arranging the plurality of second electrodes 304 in the two-dimensional array, current spreading within the semiconductor device 30 can be further improved, which helps increase luminous efficiency.

As shown in FIGS. 3A to 3D, the semiconductor device 30 further includes a first electrode pad 306 and a second electrode pad 308 located on the semiconductor epitaxial structure 10. The first electrode pad 306 is electrically connected to the first electrode 302, and the second electrode pad 308 is electrically connected to the plurality of second electrodes 304. The semiconductor device 30 may further include a first insulation structure 310 disposed between the semiconductor epitaxial structure 10 and the first electrode pad 306 and the second electrode pad 308. The first insulation structure 310 includes a plurality of first openings 310a corresponding to the plurality of second electrodes 304 and a second opening 310b corresponding to the first electrode 302. In some embodiments, one of the plurality of first openings 310a corresponds to a respective one of the plurality of second electrodes 304, i.e., the plurality of first openings 310a and the plurality of second electrodes 304 are in a one-to-one correspondence. As shown in FIG. 3C, the first electrode pad 306 may fill the second opening 310b and be in direct contact with the first electrode 302. The first electrode pad 306 and the second electrode pad 308 respectively include a metal, such as nickel (Ni), titanium (Ti), platinum (Pt), palladium (Pd), silver (Ag), gold (Au), aluminum (Al), tin (Sn), copper (Cu), bismuth (Bi), indium (In), or combinations thereof.

The semiconductor device 30 may optionally include a conductive layer 312, a metal reflective structure 314, and/or a second insulation structure 316. The second insulation structure 316 may cover the first insulation structure 310, the conductive layer 312, and the metal reflective structure 314. As shown in FIGS. 3B to 3C, the first insulation structure 310 and the second insulation structure 316 cover a sidewall S1 of the platform portion P’, a sidewall S2 of the first semiconductor structure 110, and a bottom of the recess portion C’. The first insulation structure 310 and/or the second insulation structure 316 may be a single layer or multiple layers, and includes a dielectric material such as an oxide, a nitride, a polymer, or combinations thereof, such as aluminum oxide (AlOx), silicon oxide (SiOx), titanium oxide (TiOx), niobium pentoxide (Nb₂O₅), tantalum pentoxide (Ta₂O₅), aluminum nitride (AlN), silicon nitride (SiNx), polyimide (PI) or benzocyclobutene (BCB). In some embodiments, the first insulation structure 310 and/or the second insulation structure 316 further includes a reflective structure, such as DBR mentioned above. In some embodiments, the first insulation structure 310 includes DBR and the second insulation structure 316 does not include DBR.

As shown in FIGS. 3A to 3D, the second insulation structure 316 includes a third opening 316a and a fourth opening 316b. The third opening 316a is disposed below the second electrode pad 308 and corresponds to multiple of the first openings 310a. The fourth opening 316b is disposed below the first electrode pad 306 and corresponds to the second opening 310b. The third opening 316a may have an area larger than that of the fourth opening 316b. By disposing the plurality of first openings 310a, the second opening 310b, the third opening 316a, and the fourth opening 316b, together with other conductive structures (such as the conductive layer 312 and the metal reflective structure 314), conductive paths can be formed in the semiconductor device 30 to facilitate current spreading.

The conductive layer 312 may be disposed between the first insulation structure 310 and the metal reflective structure 314. The conductive layer 312 includes a conductive oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO), or combinations thereof. As shown in FIGS. 3C and 3D, the conductive layer 312 covers the first insulation structure 310 and fills in the plurality of first openings 310a to connect the plurality of second electrodes 304, and the second electrode pad 308 connects the conductive layer 312 through the third opening 316a. In other words, the conductive layer 312 can electrically connect the plurality of second electrodes 304 with the second electrode pad 308, so as to facilitate current spreading of the semiconductor device 30. In some embodiments, the conductive layer 312 may also be an adhesion layer to improve adhesion between the first insulation structure 310 and the metal reflective structure 314, thereby enhancing structural stability of the semiconductor device 30.

The metal reflective structure 314 may be disposed between the conductive layer 312 and the second insulation structure 316. The metal reflective structure 314 includes a metal, such as gold (Au), silver (Ag), or aluminum (Al). The metal reflective structure 314 reflects the light emitted from the active structure 130, and may enhance lateral current conduction within the semiconductor device 30. As shown in FIGS. 3B to 3D, by covering the first insulation structure 310 (including the DBR) with the metal reflective structure 314, an omni-directional reflector (ODR) structure can be formed to further increase reflectivity and improve luminous efficiency. In some embodiments, the semiconductor device 30 does not have the conductive layer 312, and the metal reflective structure 314 directly contacts the first insulation structure 310 and fills in the plurality of first openings 310a to connect the plurality of second electrodes 304 (not shown).

The semiconductor device 30 may optionally include a base 300 and a bonding structure 301. The base 300 is disposed below the first semiconductor structure 110. The bonding structure 301 is disposed between the base 300 and the first semiconductor structure 110 to connect them. Descriptions of the base 300 and the bonding structure 301 may refer to the foregoing descriptions of the base 200 and the bonding structure 201.

In some embodiments, a method of manufacturing the semiconductor device 30 may include the following steps: providing the semiconductor epitaxial structure 10; performing a bonding process to bond the first semiconductor structure 110 to the base 300 by the bonding structure 301; removing the growth substrate 100 from the semiconductor epitaxial structure 10; removing a portion of the first semiconductor structure 110, the second semiconductor structure 120, and the active structure 130 to form the recess portion C’ and the platform portion P’; forming the first electrode 302 in the recess portion C’, and forming the second electrode 304 on the fourth semiconductor layer 120a. In some embodiments, the method of manufacturing the semiconductor device 30 optionally includes the following steps: forming the first insulation structure 310 including the plurality of first openings 310a and the second opening 310b on the semiconductor epitaxial structure 10; forming the conductive layer 312 on the first insulation structure 310; forming the metal reflective structure 314 on the conductive layer 312; forming the second insulation structure 316 including the third opening 316a and the fourth opening 316b on the metal reflective structure 314; and forming the first electrode pad 306 and the second electrode pad 308 on the second insulation structure 316. In some embodiments, the method of manufacturing the semiconductor device 30 optionally includes a step: removing the base 300 and the bonding structure 301 after forming the first electrode pad 306 and the second electrode pad 308. The positions, relative relationships and materials of each layer or structure as well as variations of the semiconductor device 30 may be referred to the foregoing embodiments and are not repeatedly described herein.

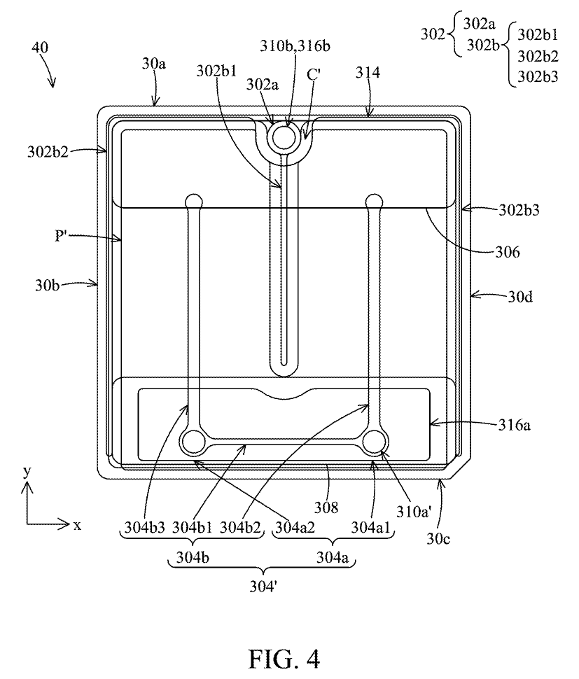

FIG. 4 is a schematic top view of a semiconductor device 40 in accordance with an embodiment of the present disclosure. The semiconductor device 40 has a structure similar to that of the semiconductor device 30, and the main difference between the semiconductor device 40 and the semiconductor device 30 is the design of the second electrode. As shown in FIG. 4, in this embodiment, a second electrode 304’ of the semiconductor device 40 includes a main portion 304a and an extending portion 304b. More specifically, the main portion 304a includes a first main part 304a1 and a second main part 304a2. The extending portion 304b includes a plurality of finger electrodes 304b1, 304b2, and 304b3. Each of the finger electrodes 304b1, 304b2, and 304b3 may have a sectional width smaller than that of the first main part 304a1 and/or the second main part 304a2. In detail, the finger electrode 304b1 connects the first main part 304a1 and the second main part 304a2 and extends along a first direction. The finger electrode 304b2 connects to the first main part 304a1 and extends along a second direction different from the first direction. The finger electrode 304b3 connects to the second main part 304a2 and extends along the second direction. The first direction may be perpendicular to the second direction. For example, the first direction and the second direction may be a +x direction and a +y direction, or +y direction and a +x direction. In this embodiment, both the first electrode 302 and the second electrode 304’ have an interdigitated electrode design to facilitate current spreading. In top view, the finger electrode 304b2 of the second electrode 304’ is located between the finger electrodes 302b1 and 302b3 of the first electrode 302, and the finger electrode 304b3 is located between the finger electrodes 302b1 and 302b2 of the first electrode 302. The positions, relative relationships and materials of each layer or structure as well as variations of the semiconductor device 40 may be referred to the foregoing embodiments and are not repeatedly described herein.

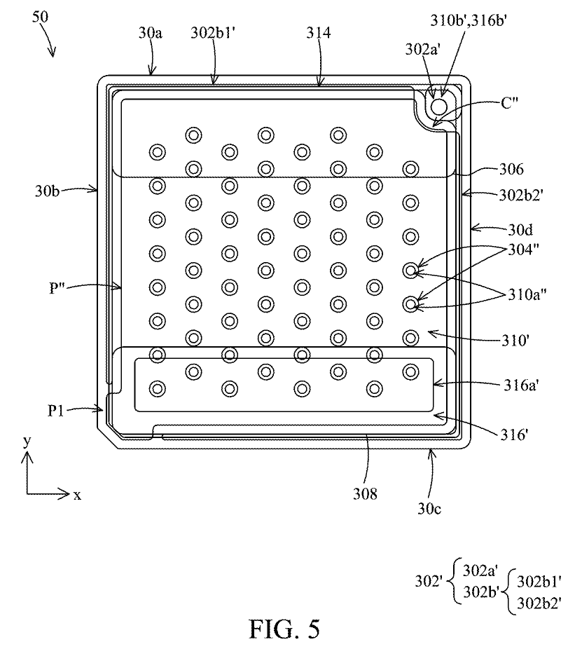

FIG. 5 is a schematic top view of a semiconductor device 50 in accordance with an embodiment of the present disclosure. The semiconductor device 50 has a structure similar to that of the semiconductor device 30, and the main difference between the semiconductor device 50 and the semiconductor device 30 is the design of the recess portion, the platform portion, the first electrode and/or the second electrode. As shown in FIG. 5, in the semiconductor device 50, a recess portion C’’ is located at a corner between the first side 30a and the fourth side 30d, and a platform portion P’’ includes a protruding portion P1 located at a corner opposite to the recess portion C’’ (i.e., the corner between the second side 30b and the third side 30c). A first electrode 302’ includes a main portion 302a’ and an extending portion 302b’, and the extending portion 302b’ includes a plurality of finger electrodes 302b1’ and 302b2’. Each of the finger electrodes 302b1’ and 302b2’ may have a sectional width smaller than that of the main portion 302a’. The main portion 302a’ is located in the recess portion C’’; the finger electrode 302b1’ connects to the main portion 302a’ and first extends along the first side 30a and then turns to extend along the second side 30b; the finger electrode 302b2’ connects to the main portion 302a’ and first extends along the fourth side 30d and then turns to extend along the third side 30c. In this embodiment, the recess portion C’’ does not extend to the center of the device as the recess portion C’ shown in FIGS. 3A or 4, so the platform portion P’’ has a larger area than the platform portion P’ shown in FIGS. 3A or 4 for disposing more second electrodes 304’’ thereon. As shown in FIG. 5, a plurality of second electrodes 304’’ of the semiconductor device 50 are arranged in a two-dimensional pattern, and the second electrodes 304’’ in any row are staggered with the second electrodes 304’’ in an adjacent row.

As shown in FIG. 5, a first insulation structure 310’ of the semiconductor device 50 includes a plurality of first openings 310a’’ and a second opening 310b’. One of the plurality of first openings 310a’’ corresponds to a respective one of the plurality of second electrodes 304’’. The second opening 310b’ corresponds to the main portion 302a’ of the first electrode 302’. A second insulation structure 316’ of the semiconductor device 50 includes a third opening 316a’ and a fourth opening 316b’. The third opening 316a’ is located below the second electrode pad 308 and corresponds to multiple of the first openings 310a’’. The fourth opening 316b’ is located below the first electrode pad 306 and corresponds to the second opening 310b’. The positions, relative relationships and materials of each layer or structure as well as variations of the semiconductor device 50 may be referred to the foregoing embodiments and are not repeatedly described herein.

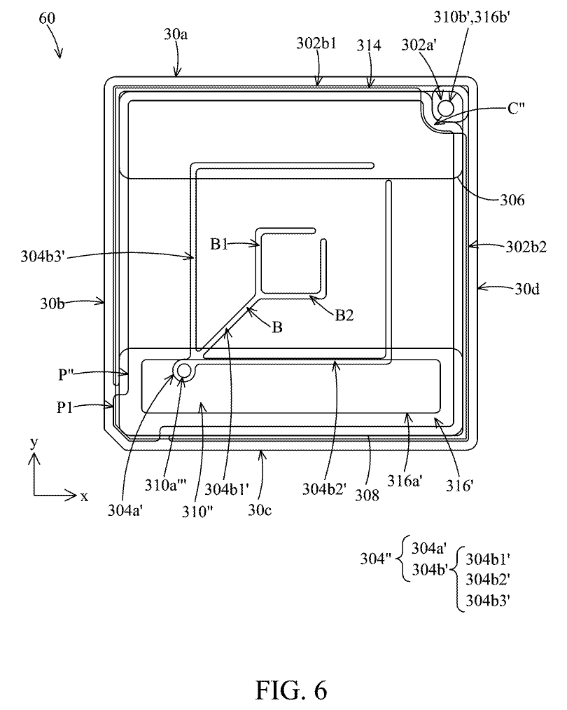

FIG. 6 is a schematic top view of a semiconductor device 60 in accordance with an embodiment of the present disclosure. The semiconductor device 60 has a structure similar to that of the semiconductor device 50, and the main difference between the semiconductor device 60 and the semiconductor device 50 is the design of the second electrode. As shown in FIG. 6, in this embodiment, a second electrode 304’’ includes a main portion 304a’ and an extending portion 304b’. The extending portion 304b’ includes a plurality of finger electrodes 304b1’, 304b2’, and 304b3’. Each of the finger electrodes 304b1’, 304b2’, and 304b3’ may have a sectional width smaller than that of the main portion 304a’. Specifically, the finger electrode 304b1’ connects to the main portion 304a’ and extends toward the recess portion C’’. The finger electrode 304b2’ connects to the finger electrode 304b1’, first extends along the +y direction, and then turns to extend along the +x direction. The finger electrode 304b3’ connects to the finger electrode 304b1’, first extends along the +x direction, and then turns to extend along the +y direction. In some embodiments, the finger electrode 304b1’ optionally includes a base part B, a first extending part B1, and a second extending part B2. The first extending part B1 connects to the base part B, first extends along the +y direction, and then turns to extend along the +x direction. The second extending part B2 connects to the base part B, first extends along the +x direction, and then turns to extend along the +y direction. As shown in FIG. 6, the finger electrode 304b2’ and the second extending part B2 may be disposed parallel to each other, and the finger electrode 304b3’ and the first extending part B1 may be disposed parallel to each other. The positions, relative relationships and materials of each layer or structure as well as variations of the semiconductor device 60 may be referred to the foregoing embodiments and are not repeatedly described herein.

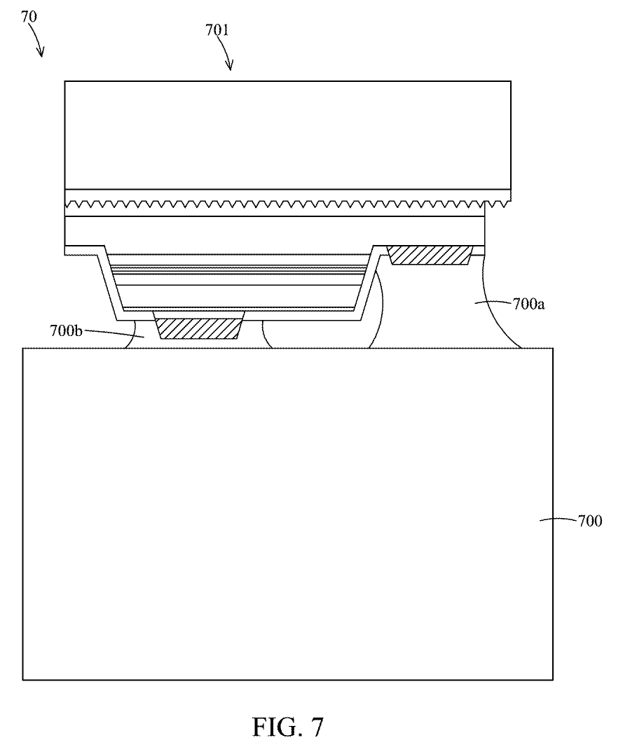

FIG. 7 is a schematic sectional view of a semiconductor apparatus 70 in accordance with an embodiment of the present disclosure. As shown in FIG. 7, the semiconductor apparatus 70 includes a carrier 700 and a semiconductor device 701 disposed on the carrier 700. Specifically, the semiconductor device 701 may be any of the semiconductor devices described in previous embodiments of the present disclosure (e.g., the semiconductor device 20, 30, 40, 50, or 60). For ease of explanation, the semiconductor device 20 is used as an example in FIG. 7. The carrier 700 may be, for example, a package submount or a printed circuit board (PCB). The carrier 700 may be a single layer or multiple layers, and may include polyester, polyimide (PI), bismaleimide triazine (BT) resin, polytetrafluoroethylene (PTFE) resin, phenol resins (PF), or glass fiber epoxy. As shown in FIG. 7, the semiconductor apparatus 70 further includes a first conductive connection portion 700a and a second conductive connection portion 700b. The semiconductor device 701 may be bonded to the carrier 700 in a flip-chip manner via the first conductive connection portion 700a and the second conductive connection portion 700b. The first conductive connection portion 700a and the second conductive connection portion 700b may include metal, such as tin (Sn).

In summary, the present disclosure provides a semiconductor epitaxial structure, a semiconductor device, and a semiconductor apparatus, which may achieve effects such as improved current spreading and increased luminous efficiency. For example: by designing the conductivity type, material, thickness, and/or dopant concentration of the first semiconductor layer, the forward voltage can be reduced, brightness can be increased, and wall-plug efficiency can be enhanced; by disposing the second semiconductor layer, the stability of the bonding process can be improved; by roughening the bottom surface of the second semiconductor layer, the light extraction efficiency of the semiconductor device can be improved; by designing the arrangement or shapes of the first/second electrodes and/or the opening positions of the first/second insulation structures, current spreading within the semiconductor device can be further improved to increase luminous efficiency; by disposing structures such as the conductive layer and the metal reflective structure, current spreading and reflectivity of the semiconductor device can be further improved, thereby enhancing emission efficiency. The semiconductor devices of the present disclosure may exhibit good performance in a high temperature operation life (HTOL) test. Specifically, the semiconductor epitaxial structure, the semiconductor device and the semiconductor apparatus of the present disclosure may be applied to products in various fields, such as illumination, display, communication or power supply system, for example, may be used in a light fixture, monitor, an automotive instrument panel, a television, computer, traffic sign, or an outdoor display device.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a semiconductor epitaxial structure, comprising:
a first semiconductor structure comprising a first semiconductor layer and a second semiconductor layer below the first semiconductor layer, and the first semiconductor layer comprising an upper surface which comprises a first region and a second region;
an active structure located on the first region and not overlapped with the second region;
a second semiconductor structure located on the active structure; and
a first electrode located on the second region and directly contacting the first semiconductor layer;
wherein the first semiconductor layer is n-type and is the thickest layer within the first semiconductor structure, and the first semiconductor layer comprises a first III-V semiconductor material, the first III-V semiconductor material comprises a ternary or quaternary arsenide, or a ternary or quaternary phosphide.

2. The semiconductor device according to claim 1, wherein the second semiconductor layer comprises a second III-V semiconductor material different from the first III-V semiconductor material.

3. The semiconductor device according to claim 1, wherein the first III-V semiconductor material comprises AlGaAs or AlGaInP.

4. The semiconductor device according to claim 1, wherein the first semiconductor layer comprises a thickness in a range of 2 μm to 8 μm.

5. The semiconductor device according to claim 1, wherein the first semiconductor layer comprises a first dopant with a doping concentration in a range of 5x10¹⁷ cm⁻³ to 5x10¹⁸ cm⁻³.

6. The semiconductor device according to claim 5, wherein the second semiconductor layer comprises a second dopant with a doping concentration smaller than that of the first dopant in the first semiconductor layer.

7. The semiconductor device according to claim 1, wherein the second semiconductor layer comprises a bottom surface opposite to the first semiconductor layer, and the bottom surface is roughened.

8. The semiconductor device according to claim 1, wherein the first semiconductor structure further comprises a third semiconductor layer located between the first semiconductor layer and the active structure.

9. The semiconductor device according to claim 1, further comprising a second electrode disposed on the second semiconductor structure.

10. The semiconductor device according to claim 9, wherein the second semiconductor structure comprises a fourth semiconductor layer and a fifth semiconductor layer located between the fourth semiconductor layer and the active structure, and the second electrode directly contacts the fourth semiconductor layer.

11. The semiconductor device according to claim 10, wherein the fifth semiconductor layer has a width larger than that of the fourth semiconductor layer.

12. The semiconductor device according to claim 10, wherein the fourth semiconductor layer comprises a third III-V semiconductor material and the fifth semiconductor layer comprises a fourth III-V semiconductor material different from the third III-V semiconductor material.

13. The semiconductor device according to claim 12, wherein the fourth III-V semiconductor material and the first III-V semiconductor material are the same.

14. The semiconductor device according to claim 10, wherein the second semiconductor structure further comprises a transition layer located between the fourth semiconductor layer and the fifth semiconductor layer.

15. The semiconductor device according to claim 1, further comprising a base disposed below the second semiconductor layer.

16. The semiconductor device according to claim 15, further comprising a bonding structure connecting the base and the second semiconductor layer.

17. The semiconductor device according to claim 1, further comprising a first insulation structure covering the semiconductor epitaxial structure, and the first insulation structure comprises an opening corresponding to the first electrode.

18. The semiconductor device according to claim 17, wherein the first insulation structure comprises a Distributed Bragg Reflector.

19. The semiconductor device according to claim 17, further comprising a metal reflective structure disposed on the first insulation structure and covering the second semiconductor structure.

20. The semiconductor device according to claim 19, further comprising a second insulation structure disposed on the metal reflective structure and covering the metal reflective structure and the first insulation structure.
